(19) United States
(12) Patent Application Publication
(10) Pub. No.: US 2021/0326498 A1
(43) Pub. Date: Oct. 21, 2021

(54) METHOD AND COMPUTER PROGRAM PRODUCT FOR COMPARING A SIMULATION WITH THE REAL CARRIED OUT PROCESS

(71) Applicant: ENGEL AUSTRIA GmbH, Schwertberg (DE)

(72) Inventors: Paul Joachim WAGNER, Asten (AT); Georg PILLWEIN, Linz (AT)

(21) Appl. No.: 17/232,814

(22) Filed: Apr. 16, 2021

(30) Foreign Application Priority Data
Apr. 20, 2020 (AT) A 50339/2020

(51) Int. Cl. G06F 30/20; B29C 45/76

(52) U.S. Cl. CPC G06F 30/20; B29C 45/76

(57) ABSTRACT

A method for aligning a simulation of a process to be carried out with a shaping machine with the process really carried out, includes calculating a simulation progression of a variable characteristic of the process, measuring in the process really carried out a measurement progression of the characteristic variable, determining first distinguishing points of the curve of the simulation progression and second distinguishing points of the curve of the measurement progression, mapping the first distinguishing points and the second distinguishing points, calculating a modification parameter for the simulation and/or the process from coordinates of the first distinguishing points and second distinguishing points mapped to each other, and modifying the simulation and/or the process based on the modification parameter and carrying it out again.

### BACKGROUND OF THE INVENTION

The present invention relates to a method for aligning a simulation of a process to be carried out with a shaping machine with the process really carried out, as well as a computer program product for aligning a simulation of a process to be carried out with a shaping machine with the process really carried out.

Shaping machines can be injection-molding machines, transfer-molding presses, compression-molding presses and the like.

In the following, the state of the art is summarized by reference to injection-molding processes as an example of processes to be carried out with shaping machines. Analogous conclusions apply to general processes to be carried out with shaping machines.

It is known to carry out simulations which model the injection of a thermoplastic material into a mold cavity, for example in order to define or to improve settings of the injection-molding machine.

Here the problem arises that the results of the simulation sometimes differ significantly from the injection-molding process really carried out. There are various approaches to solving this problem in the state of the art. One example would be disclosed in AT 519096 A1 by the applicant, wherein various simulations are carried out and later an alignment between the real conditions on the shaping machine and the simulation results is carried out.

A direct alignment of the simulation with an injection-molding cycle really carried out is also known per se. For example, this alignment is carried out by hand in US 2002/0188375 A1.

A completely automatable method is described in the as yet unpublished Austrian patent application A 50885/2019 by the applicant. Here, either the simulation progression or the measurement progression is transformed in order to obtain a quantification of the deviation which can then be used subsequently for the reproducible and reliable adjustment of the simulation.

### SUMMARY OF THE INVENTION

The object of the present invention is to specify a possibility by which the simulation of a process to be carried out with a shaping machine and the process really carried out can be aligned reproducibly—and preferably in at least partially automatable manner.

With respect to the method in which:
within the framework of the simulation, at least one simulation progression of a variable that is characteristic of the process, in particular a simulated pressure progression, is calculated,
in the process really carried out at least one measurement progression of the characteristic variable, in particular a measured pressure progression, is measured,
first distinguishing points of the curve of the at least one simulation progression and second distinguishing points of the curve of the at least one measurement progression are determined,
the first distinguishing points and the second distinguishing points are at least partially mapped to each other,
at least one modification parameter for the simulation and/or the process is calculated from coordinates of the first distinguishing points and second distinguishing points at least partially mapped to each other, and
the simulation and/or the process is modified on the basis of the at least one modification parameter and carried out again.

With respect to the computer program, the object is achieved by commands which prompt a computer executing them:
to calculate at least one simulation progression of at least one variable that is characteristic of the process, in particular a simulated pressure progression, within the framework of a simulation or to receive one from a separate simulation,
to receive at least one measurement progression of the at least one characteristic variable, in particular a measured pressure progression, from the real process,
to determine first distinguishing points of the curve of the at least one simulation progression and second distinguishing points of the curve of the at least one measurement progression,
to at least partially map the first distinguishing points and the second distinguishing points to each other,
to calculate at least one modification parameter for the simulation and/or the process from coordinates of the first distinguishing points and second distinguishing points mapped to each other, and
to modify either the simulation and/or the process on the basis of the at least one modification parameter and to carry it out again
or to output instructions which include that the simulation and/or the process is to be carried out again and what modifications are to be made to the simulation and/or the process on the basis of the at least one modification parameter.

The first distinguishing points and the second distinguishing points of the curves of the at least one simulation progression and the at least one measurement progression are points which can be determined based on features of these curves. These can be, for example, “kinks” in the curve or inflection or saddle points as well as minima or maxima. These points are therefore “distinguishing” or recognizable due to these properties.

It should be mentioned that it is known per se to search the at least one measurement progression and the at least one simulation progression for such points and to map the points to each other, see WO 2016/177513 A1. There, however, the points are used only to determine positions of the flow front within the real injection-molding tool and it is not provided to carry out the simulation again.

A central aspect of the invention is that in fact much more information is present in the coordinates of the first distinguishing points and the second distinguishing points than is utilized in WO 2016/177513 A1, namely to the point that the simulation can be adjusted in a targeted manner according to the invention for the alignment with the real process (or the other way round: the process with the simulation). “In a targeted manner” in this case means that the modification parameters according to the invention (which can be calculated as numerical values) can quantify the deviation between the at least one simulation progression and the at least one measurement progression, which naturally allows a more precise matching of the simulation to the process.

In other words, according to the invention, modification parameters can be calculated from the coordinates of the first distinguishing points and the second distinguishing points (as a value) in order to adjust the simulation such that the simulation result substantially corresponds to the real process or at least lies closer to the real process. The modification parameters can alternatively or additionally be used to adjust the process such that the measurement result substantially corresponds to the simulation result or at least lies closer to it.

The at least one measurement progression and/or the at least one simulation progression can consist of a plurality of individual calculated and/or measured points which in their entirety form a progression, which is naturally a procedure known per se. However, it is in principle also conceivable to define “continuous” progressions—for example graphically.

The first distinguishing points and the second distinguishing points can be determined by measures known per se from the at least one simulation progression and the at least one measurement progression, e.g. using the Ramer-Douglas-Peucker algorithm.

In a simple example, the mapping of the first distinguishing points and the second distinguishing points to each other can be achieved substantially through the sequence of the distinguishing points. For the case that the number of distinguishing points differs for the simulation progression and the measurement progression, various methods can be used in order to achieve the mapping. Examples thereof will be given later.

Within the framework of the invention, the first distinguishing points and the second distinguishing points are at least partially mapped to each other. The partial mapping can result for example from the fact that—as mentioned—fewer first distinguishing points than second distinguishing points are present (or vice versa).

Within the framework of the present document, by “mapping” is meant in each case that this can also be a partial mapping within the meaning of the invention, unless explicitly indicated otherwise.

In particular in the case of an injection-molding process as molding process, at least one of the following can be used as variable that is characteristic of the process (or a sub-process thereof): a spraying pressure (injection pressure), a molding material pressure, a melt pressure, a mold internal pressure, a mold internal temperature, a molding material temperature, an injection speed, a driving torque, an injection capacity, a mold breathing, a real volume flow rate.

Naturally, variables other than the characteristic variable can also be calculated or more than one characteristic variable can be calculated by means of the simulation according to the invention. Corresponding variables would be pressures, temperatures, viscosities, bulk moduli (or compressibilities), shear rates and the like.

In principle, the method according to the invention can be carried out after the simulation and after the real process (or at least one cycle of the same).

In this connection, it should be mentioned that the sequence of the method steps according to the invention is predefined only by logic and not by the sequence in the independent claims. For example, it is entirely possible first to carry out the real process and then the simulation, or vice versa.

As already mentioned, by shaping machines may be meant, for example, injection-molding machines, transfer-molding presses, compression-molding presses and the like. Accordingly, the invention can be used for any process for which a corresponding simulation variant is present. This includes, for example, foaming methods, multi-component injection molding, thermoset molding methods, silicone molding methods, elastomer molding methods, co-injection methods, injection compression molding, variothermal tempering, reactive methods and the like.

The materials processed using these processes are also referred to as molding material. The molding material can preferably be a thermoplastic material, the molding process can preferably be an injection-molding process. In injection-molding processes, additions, such as fibers, gases or powders, can, however, certainly be added to the plastic as loads.

In general, however, it is not only thermoplastic material that can be used in the process to be dealt with according to the invention, which is to be carried out with a shaping machine. For example, reactive molding materials or also certain ceramics can be used. In general, the materials which are thus used in the process are referred to as molding materials.

The variable that is characteristic of the process can in particular be characteristic of a sub-process of the process. In the example of an injection-molding process, it can be a variable that is characteristic of the injection procedure, for example.

The alignment between the simulation and the real process is naturally not to be taken to mean that the simulation results are intended to correspond exactly to reality after the alignment, because this would naturally be impossible due to inaccuracies from measurements and approximations that are always present. Rather, the real process is to be viewed in contrast to the virtual or simulated process, which is calculated virtually within the framework of the (computer) simulation. On the one hand the “true” process and on the other the approximate calculation thereof are thus meant.

Within the meaning of the invention, by simulations are meant computer simulations which simulate physical and/or chemical processes, which occur during the process to be considered, by means of a mathematical model. Within the meaning of the invention, however, there are no limitations as to how simple or complex these models have to be. That is to say, there are in principle no restrictions as to how “realistically” or accurately the simulations model reality. In particular, the simulations can contain approximations and analytical partial calculations—in addition to the calculation inaccuracy that is present in any case.

Nor do the simulations have to model the whole process. In particular, in the case of injection-molding processes it is possible for only the filling procedure (injection procedure) to be simulated, for example. Naturally, it is equally also conceivable to simulate the substantially complete process, in which the machine behavior can for example also be included.

It is an advantage of the invention that deviations between simulation and the real process, which arise through simulation of only a sub-process of the process, can also be recognized and/or compensated for.

The use of simulation software, whether it be for designing plastic articles and associated tools, for error correction or for the optimization of processes in the field of injection molding and other methods connected thereto, has been increasing for years and will also increase further in the future.

Alongside the many advantages that simulations bring with them (e.g. cost saving during tool construction, since faults/problems can already be corrected in advance or time saving during fault finding in the case of an existing tool), it must be noted that a simulation can only partly model reality accurately. The more accurate the design of the simulation models (geometry, material models, initial and boundary conditions, etc.), the better they can also reproduce reality. Therefore the aim is to model the simulation as accurately as possible, in order that the calculated simulation values come as close as possible to the measurement values of a real process.

Unfortunately, this is not always possible since, for example, certain geometries (hot runner, nozzle, space in front of the screw) and settings or items of information (forming mass temperature, friction losses, decompression, behavior of the non-return valve, etc.) are not available from and on the machine etc., and for example material models which are used in the simulations do not model the real material behavior 100% accurately (materials even of the same type vary from batch to batch or material parameters are not stored in the simulation for a particular material).

For this reason, deviations from the real process will normally occur in the results of a simulation carried out, which was modelled using data, knowledge and settings already available.

If the results (i.e. of the variables that are characteristic of the process, such as e.g. pressures, temperatures, etc.) from simulation and the real process are available, the simulation results are aligned according to the invention. This means that it is attempted to adjust the simulation model such that the same (or at least approximated) results as in the real process are obtained when the altered simulations are carried out again. This can be effected e.g. by altering injection profiles, forming mass temperatures, material models, geometries, etc. in the simulation model. As is noted, a large number of parameters can be adjusted for an alignment of simulation and the real process. The problem in this case is that it is not known which parameters have to be adjusted and to what extent, in order to obtain an adequate alignment. In particular, with the operator's naked eye, such as is provided for in the state of the art, inaccurate and unreproducible results are naturally obtained here.

To date, it has been usual in this case e.g. to carry out parameter studies with a large number of different variants of different combinations of parameters with changing values. By chance or even with a certain system, an alignment can then be achieved with a particular combination of parameters. The disadvantage here is that a large number of simulations or attempts have to be carried out before an adequate alignment can be achieved, and in addition it is difficult to be able to tell why which parameters had to be altered in the simulation or in the process, and to what extent, for the alignment.

The rectification of this problem is a further achievement of the invention.

Before additional parameter studies have to be carried out by the Trial & Error method in order to find the correct parameter settings for the simulation, the simulation can accordingly be adjusted (or analogously the process matched to the simulation) in one go in the following step with the aid of the calculation according to the invention of the modification parameters, and countless simulations need not be started or attempts carried out. This saves time and effort and through the calculated modification parameters it is possible to accurately tell what has not been modelled correctly in the simulation in comparison with the real process.

By knowing the particular modification parameters, material models or the associated material parameters can for example be altered in the simulation model. This is a major advantage because firstly sufficient material parameter data are not available for many materials and secondly material data of one material type can vary from batch to batch. By adjusting the material model, this deviation can be effectively compensated for.

Data of the dead volume are often not modelled in a simulation model or the effects of the dead volume cannot be determined correctly, because the data required for this are not available or are only available incompletely. With the correct modification parameters these deviations between simulation and the real process can also be quantified and the simulation can then be aligned accordingly.

With the invention it is also possible to adjust the boundary conditions (i.e. for example settings of the shaping machine) of the process such that the measurement (thus the at least one measurement progression) corresponds as accurately as possible with the simulation (i.e. the at least one simulation progression). In other words, boundary conditions not taken into account in the simulation can be compensated for by adjusting boundary conditions of the process, which can result in a better correspondence between simulation and experiment (i.e. the real process carried out on the shaping machine).

The following boundary conditions could for example be altered in the process for a better correspondence between simulation and process:
Adjust the forming mass temperature (directly or indirectly by altering the hot runner temperature, the set cylinder temperatures and/or the tool temperature) in order to better align e.g. measured and calculated pressures.
Alteration of the material composition in order to better correspond to the material model parameters used in the simulation.
Supply flow temperatures, flow rates and/or temperature differences for the tool tempering can be approximated to the simulated values.
The holding pressure level and holding pressure time can be altered corresponding to the difference between simulated and measured warpage of the component. In addition, the holding pressure level can be adjusted for example using a factor which results from the division of simulated and measured mold internal pressures.
The metering stroke, changeover point and/or the decompression can be chosen such that the injection volume better corresponds with the simulation.
The injection volume flow profile can be adjusted, e.g. in order to achieve the total injection time from the simulation in the real process, etc.

Protection is likewise sought for a shaping machine which is set up to carry out the methods according to the invention.

For this purpose, various sensors can be present in order to measure the variables that are characteristic of the process and optionally further variables. These can be connected or connectable to a central machine control system of the shaping machine. The methods according to the invention can be implemented on this machine control system by means of software, i.e. the central machine control system can represent the computer on which the computer program product according to the invention can be executed.

The executing computer can alternatively also be arranged remote from the shaping machine and connected to various elements of the shaping machine via a remote data transmission connection, e.g. in the form of a computer server connected in this way. Finally, the computer can also be realized by distributed computing, i.e. the functions of the open- and/or closed-loop control unit are then executed by a plurality of computing processes, which can run on different computers independently of the position of the shaping machine.

All aspects described and claimed in relation to the method according to the invention can also be provided in the computer program product according to the invention or be implemented as one or as part of one.

In a particularly preferred embodiment, the automatic execution of the methods according to the invention is provided or, in other words, the computer program products according to the invention are designed to automatically execute the corresponding commands. However, a manual or partially automated implementation of the invention is naturally also conceivable.

The simulation can consist of partial simulations or, for one simulation result, several simulations of the physical and/or chemical process can be carried out, the results of which can be combined.

It has already been mentioned that the first distinguishing points and/or the second distinguishing points can be determined using the Ramer-Douglas-Peucker algorithm known per se.

A set of points (which form a progression) can be reduced by means of this algorithm, with the result that the given progression, optionally by specifying certain criteria, nevertheless still reflects the original progression (up to a certain predefinable degree) through the reduced point set.

Examples of conditions that can be predefined in order to ensure that the progression is distorted only within certain limits would be at least one of the following: a tolerance range around the original progression, a maximum number of reduced points, a minimum distance between reduced points, maximum standardized error of the squares of the squares of the distance between the starting points and reduced points.

The point set (of the at least one simulation progression and/or of the at least one measurement progression) reduced with the aid of the Ramer-Douglas-Peucker algorithm can be further reduced by using at least one additional criterion, in order to obtain the first distinguishing points and/or the second distinguishing points.

In the context of this criterion or independently of the Ramer-Douglas-Peucker algorithm, the first distinguishing points and/or the second distinguishing points can for example accordingly be determined, if connecting lines to adjacent points of the at least one simulation progression or the at least one measurement progression form an angle which deviates by a predefined angular amount—preferably by 5° or more, particularly preferably by 10° or more—from 180°.

In summary, at least one of the following conditions and/or criteria can be used when determining the first distinguishing points and/or the second distinguishing points:
a maximum number of reduced points and/or distinguishing points,
a minimum distance between the points of the reduced point set,
a maximum standardized error of the squares of the distance between the original data points of the measurement progression (MV) and/or of the simulation progression (SV) on the one hand and the points of the reduced point set on the other,
exceeding and/or reaching a threshold value through the characteristic variable (for example in the form of a pressure threshold),
excluding a predefined partial range of the process, wherein the partial range is given by absolute or relative limits.

The predefined partial range can, as mentioned, be given by absolute limits (e.g. 15 ms after the start of the injection procedure). Relative limits can result through a proportion of the whole process (e.g. omitting the first 10% of an injection procedure relative to the time or a time-equivalent variable) or by reaching a certain situation in the process (e.g. double the injection stroke length which, according to experience, is required until the non-return valve is closed).

Slope analysis (with formation of the first derivative of the at least one simulation progression and/or of the at least one measurement progression), an analysis of inflection points (with formation of the second derivative of the at least one simulation progression and/or of the at least one measurement progression) and/or an analysis of minima and/or maxima of the at least one simulation progression and/or of the at least one measurement progression can alternatively or additionally be used to determine the first distinguishing points and/or the second distinguishing points.

Before the first distinguishing points and/or the second distinguishing points are determined, the at least one simulation progression and/or the at least one measurement progression can
be filtered in order to filter out noise superimposed on the at least one simulation progression and/or the at least one measurement progression, and/or
be scaled, in particular standardized, (e.g. in order to make angular relationships comparable or usable), wherein the reduced point set and/or the first distinguishing points and/or the second distinguishing points can then be scaled back again.

The first distinguishing points and the second distinguishing points can be at least partially mapped to each other, in that
for all of the possible different options for mapping the first distinguishing points to the second distinguishing points, the first distinguishing points and/or the second distinguishing points are scaled and/or shifted such that in each case two of the first distinguishing points and of the second distinguishing points substantially lie on top of each other,
in each case at least one characteristic number for the quality of the respective mapping option is calculated on the basis of at least one of the following: scaling parameter, shifting parameter, (coordinate) differences between the—optionally scaled and/or shifted—first distinguishing points and the—optionally scaled and/or shifted—second distinguishing points,
that mapping option is selected, at least one characteristic number of which indicates a best quality of the mapping.

For the calculation of the at least one characteristic number, at least one of the following can for example be used (preferably in the form of (error) squares):
parameters from the scaling and/or shifting (offset) for placing the in each case two points of the first distinguishing points and of the second distinguishing points on top of each other and/or
(coordinate) differences between the—optionally scaled and/or shifted—first distinguishing points and the—optionally scaled and/or shifted—second distinguishing points.

In principle, other methods known from the state of the art can naturally also be used in order to achieve the mapping of the first distinguishing points and the second distinguishing points.

The method according to the invention can also be applied to results of the simulation carried out again and/or to measurements in the process carried out again, wherein this is preferably repeated until a simulation deviation between the at least one simulation progression and the at least one measurement progression is sufficiently small according to a predefined criterion.

The following would be examples of criteria which can be used to interrupt the thus-started loop:
A limit value could for example be used for the at least one modification parameter itself as it quantifies the deviation. That is to say, the simulation or the process is then good enough when the at least one modification parameter falls within a certain value range. In addition, a weighting can be used to reflect that, for example, at higher pressures a better correspondence is necessary than at low pressures, and vice versa.
Areas under the simulation progressions and the measurement progressions and/or maximum values of the same can be compared.
A tolerance range for the deviation of the simulation progression from the measurement progression (or vice versa) can be established, within which the simulation is classified as good enough within the scope of the criterion.

Of course, all (inclusive and/or exclusive) combinations of these criteria can also be used.

The limit values and/or tolerances can be chosen such that:
a difference of less 10%, preferably 5% and particularly preferably 1%, results with respect to a volume of the molding material or
a difference of less than 20%, preferably less than 10% and particularly preferably less than 1%, results with respect to a pressure of the molding material.

The at least one modification parameter can relate to a magnitude of a time shift between the first distinguishing points and second distinguishing points mapped to each other, and the time shift is in particular caused by an unknown volume of the molding material present in the shaping machine. In other words, the mapping of the first distinguishing points and the second distinguishing points can be used to determine a time shift between the simulation progression and the measurement progression.

The simulation can then be modified by modifying an injection volume (e.g. in the form of a filling volume) predefined for the simulation and/or an injection volume flow rate (e.g. in the form of a filling volume flow rate) predefined for the simulation on the basis of the at least one modification parameter for the magnitude of the time shift.

In the case of a shift along a time axis—or equivalent: along an actuator position for an injection procedure—in particular the injection volume or the injection volume flow rate may not match up between simulation and real process, because the machine behavior is in many cases not detected by the simulation and an incorrect injection volume flow rate or an incorrect injection volume is used as starting point for the simulation. This can be recognized and corrected—preferably in an automated or partially automated manner—with the present invention.

If the process is alternatively or additionally to be adapted to the simulation (e.g. by altering the settings of the shaping machine), the metering stroke can for example be modified in order to align the injection volume of the process with that which was/is used in the simulation.

The at least one modification parameter can relate to a magnitude of a scaling of those coordinates of the first distinguishing points and second distinguishing points mapped to each other which correspond to the characteristic variable. In short, the modification parameter can thus relate to the magnitude of the scaling of the at least one characteristic variable or of the (first and/or second) distinguishing points.

That is to say, the scaling can for example be a multiplication of the characteristic variable by the at least one modification parameter as factor.

The simulation can then be modified by modifying a material parameter predefined for the simulation on the basis of the at least one modification parameter for the magnitude of the scaling.

In many cases, a material model or material parameter which does not reflect reality accurately enough forms the basis of an incorrectly scaled simulation result. This can also be recognized and corrected—preferably in an automated or partially automated manner—by the invention.

A Cross-WLF model and/or a 2-domain Tait pvT model can be used as material model for the simulation. The Cross-WLF model is discussed by way of example slightly further below. The Tait pvT model is based on the following state equation:

$$v ( T , p ) = {v}_{0} ( T ) [ 1 - C ln ( 1 + \frac{p}{B ( T )} ) ] + {v}_{t} ( T , p )$$

A detailed description of the parameters and the included functions can be taken from the relevant literature.

A scaling deviation between the at least one simulation progression and the at least one measurement progression could alternatively or additionally also be compensated for, for example, by altering the melt temperature in the real process. This is because for example a higher melt temperature results in a lower viscosity in the molding material (analogously: higher viscosity at a lower molding material temperature), which manifests itself in a lesser or greater progressivity (i.e. the at least one measurement progression rises more slowly or quickly) of the characteristic variable in the form of the injection pressure.

The at least one modification parameter can be calculated as a statistical parameter, in particular arithmetic mean, of the coordinates of the first distinguishing points and second distinguishing points mapped to each other. Instead of an arithmetic mean, any other desired statistical parameters, such as for example a median, can naturally also be used.

Instead of using simple statistical functions, the modification parameters based on the coordinates of the first and second distinguishing points can also be calculated for example using optimization algorithms or regression methods or any other desired functional relationships.

The at least one modification parameter can be stored in a database and used when simulating and/or setting a separate process.

During use of the invention, namely valuable data can be collected which can be used effectively to further improve simulations of processes and during the discovery of settings for a plurality of shaping machines and processes carried out therewith (swarm intelligence). That is to say, the generated data can be collected in centralized and/or decentralized databases (on premise, cloud) and thus continue to be used. Models of the closing behavior of non-return valves or material models which can then be supplied from extended material databases would be specific examples of aspects of simulations which can be improved by means of the generated data.

Several simulation progressions and/or several measurement progressions can be taken into account when determining the first distinguishing points and/or the second distinguishing points. For this purpose, mean values for the measurement progressions and/or the simulation progressions can for example be generated, which can then be used as a basis for the determination of the first distinguishing points and/or of the second distinguishing points. First distinguishing points and/or second distinguishing points can alternatively or additionally be determined individually for each of the simulation progressions and/or measurement progressions and mean values can then be used in order to determine the final distinguishing points. Instead of mean values, medians or other statistical parameters can naturally also be used.

Likewise, several simulations and several measurements with different boundary conditions can also be considered at the same time and first distinguishing points and/or second distinguishing points can be determined individually for each of the simulation progressions and/or measurement progressions in order to be able to take the dependencies on these boundary conditions into account when calculating the modification parameters.

The at least one simulation progression and/or the at least one measurement progression can be parameterized by means of a time index or a position index of an actuator used in the process, in particular of a plasticizing screw.

In the most general case, any desired variables of the process which correlate with the progress of the process can be used as such an index (for example “X axis” of the progression). Further preferred examples are: a volume of the molding material within a particular area (for example inside the molding cavity in the case of an injection-molding process), a volume flow rate (for example into the molding cavity), (target or actual value of) an actuator position, an actuator speed (e.g. of the screw), a (representative or mean) shear rate.

This means that, for example, the at least one measurement progression can then consist of pairs of values with an index parameter and a value of the variable that is characteristic of the molding process (analogously possible for the at least one simulation progression).

Instead of a time parameter, an actuator position of an actuator used in the molding process can also be used. In the example of an injection-molding process, the distance that the screw (or any other injection ram) travels during the injection can for example be used, which is also referred to as screw advance. Because the movement of the actuator is generally predefined via a profile, it would be possible to convert the mentioned progressions and positions between a time indexing and a position indexing of the actuator.

If the movements of the actuator are not also detected in the simulation, analogous parameters can nevertheless be used since boundary and/or initial conditions have to be predefined in the simulation in order to model the process. For example, an injection volume flow profile can be defined via virtual actuator positions, which represent equivalents of the actuator positions in the real process.

Alternatively, the actuator positions from the real process can be used in order to define a volume index, which corresponds to the injection volume flow profile for the simulation and can be used as time index. To accurately align the volume index from the simulation and from the real process is a further achievement of the invention.

### BRIEF DESCRIPTION OF THE DRAWINGS

Further advantages and details of the invention are revealed by the figures as well as the associated description of the figures. There are shown in:

FIG. 1 shows an example of an injection-molded part including sprue, nozzle, measuring flange and part of the space in front of the screw, which is used as an example to illustrate the invention,

FIG. 2 shows a measurement progression and a simulation progression for the example molding process in a graph,

FIG. 3 shows the measurement progression alone in a graph,

FIGS. 4 to 6 are three graphs to illustrate the determination of the second distinguishing points,

FIG. 7 shows the simulation progression alone in a graph,

FIGS. 8 to 10 are three graphs to illustrate the determination of the first distinguishing points,

FIGS. 11 to 13 are three graphs to illustrate filling states during the filling of the cavity for molding the injection-molded part from FIG. 1,

FIGS. 14 and 15 are two graphs to illustrate a mapping of the first distinguishing points and the second distinguishing points to each other in a first example,

FIGS. 16 and 17 are two graphs to illustrate an adjustment of the injection volume flow profile used in the example simulation,

FIGS. 18 and 19 show two simulation results, in each case after an alignment according to the invention, and the associated measurement progression,

FIGS. 20 to 32 are graphs to illustrate a general algorithm for mapping the first distinguishing points and the second distinguishing points in a second example.

### DETAILED DESCRIPTION OF THE INVENTION

The following embodiment examples relate to an injection process as sub-process of an injection-molding process. An injection pressure was chosen as variable that is characteristic of this process. The example simulation progression SV and the example measurement progression MV are therefore in each case a pressure progression. Of course, the invention functions analogously for other processes carried out with a shaping machine.

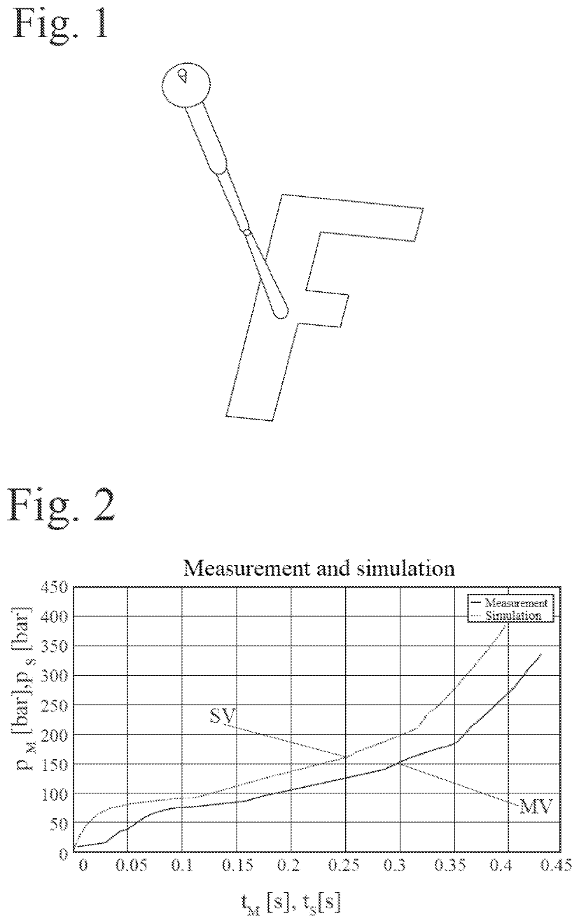

In all graphs (except FIGS. 1, 11 to 13 as well as 16 and 17), the “Y axis” is therefore the pressure in the real or simulated molding material (as variable that is characteristic of the molding process), denoted as coordinates p_{M,i} or p_{S,i} for measured and simulated pressures. The “X axis” is a time parameter (coordinates t_{S,i} and t_{M,i}), in order to record the development of the characteristic variable over time.

The time could, however, be parameterized just as well with the aid of equivalent volumes Vₘ and Vₛ. That is to say, the time could be parameterized through a (known, in the simulation progression SV optionally virtual) screw movement and converted into an equivalent volume via the known diameter of the barrel.

FIG. 1 shows an example of a molded part (in the form of a letter “F”) including sprue, nozzle, measuring flange and part of the space in front of the screw, which is to be produced in an injection-molding process according to the invention and the production of which is to be simulated at least partially according to the invention.

FIG. 2 shows a measured (measurement progression MV) as well as in addition a simulated (simulation progression SV) pressure curve, wherein values from the real injection process have been used as initial and boundary conditions for the simulation. The deviation can be easily recognized. The two curves do not correspond, since for example material parameters which are used in the simulation do not correspond with the properties of the really injected material, or because e.g. the decompression as well as the behavior of the non-return valve were not taken into account in the simulation.

It can be recognized that the simulation progression SV represented in FIG. 2 consists of a plurality of individual data points, which together represent a progression. The number of data points in the measurement progression MV is so large that this is no longer recognizable in the representation of the measurement progression MV.

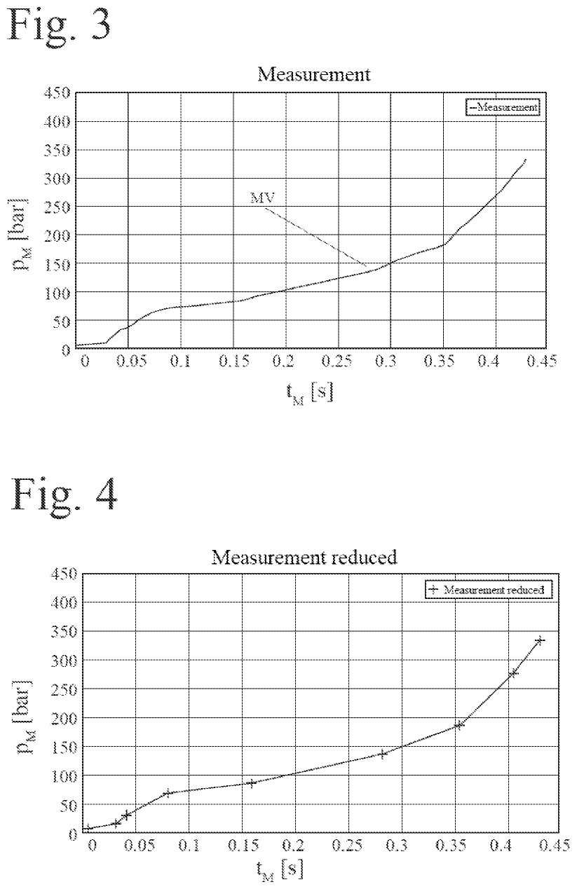

FIG. 3 shows the measurement progression MV from FIG. 2 on its own. It can be seen with the naked eye that the measurement progression contains kinks, which are an example of second distinguishing points P_{M,i} within the meaning of the invention. The kinks can be associated with a molding material front meeting obstacles in the gating system or in the molding cavity or with the volume flow that comes from the shaping machine changing rapidly for other reasons.

The reproducible and (partially) automatable finding of the first distinguishing points P_{S,i} and of the second distinguishing points P_{M,i} is described below, wherein i is used in each case as index for numbering the points.

Before finding the distinguishing points, the measurement progression MV and/or the simulation progression SV can first be filtered, wherein this is not absolutely necessary within the framework of the invention. The Savitzky-Golay filter, known per se, can e.g. be used as filter. A filter can be used to be able to filter out noise in the signal, which in most cases is not needed for finding distinguishing points.

A measurement progression MV (see FIG. 3), which consists e.g. of 10,000 recorded data points, can then be reduced to a smaller number of measurement points using algorithms known per se. In the present embodiment example, the Ramer-Douglas-Peucker algorithm (RDP algorithm) was used. The result is represented in FIG. 4, wherein connecting lines are drawn in between the individual points of the reduced point set.

The measurement progression MV with the high number of data points is reduced here only to the extent that the reduced point set lies within a certain tolerance range around the original measurement progression MV. Experts can choose this tolerance range and possibly subsequent further conditions (more on this later) depending on the application and at will.

Experts can, for example depending on whether a large or small number of reduced points are desired, define the conditions for the algorithm, wherein a few experiments can be carried out if very specific requirements are made of the reduced point set.

By using the algorithm a reduced point set of the measurement progression MV is therefore obtained, which consists of various kinks (the reduced point set). These kinks represent points wherein e.g. the slope could have changed significantly (which naturally depends on the reduction algorithm and the tolerance settings thereof).

In the specific embodiment example presented here, the Ramer-Douglas-Peucker algorithm was applied to the measurement signal (thus the measurement progression from FIGS. 2 and 3). Here, the measurement progression MV was in each case first standardized to 1 on the X axis as well as on the Y axis and then the RDP algorithm was applied thereto. The tolerance, how far the reduced measurement progression may deviate from the original measurement progression, can in principle be freely chosen here. However, it may be advisable for the tolerance to lie in a range between 0.1% and 5%. For this embodiment example a tolerance of 1.5% was chosen. The result of the algorithm is represented in FIG. 4, wherein the mentioned standardization to 1 of the two axes was reversed again, i.e. was scaled back. This scaling back can also be carried out after the application of additional conditions and/or criteria (see below).

The new reduced measurement progression MV—thus the reduced point set—was reduced here to a total of 9 measurement points and following this to 7 kinks (i.e. the boundary points are omitted because no kink angles can be described for them as below).

Before, during or following the application of the algorithm, still further conditions can be introduced in order to further restrict the reduced point set. Alternatively, the reduced point set obtained from the algorithm can be used directly as the second distinguishing points P_{M,i}.

Further (secondary) conditions for reducing the point set can be, for example:
a maximum number of reduced points or distinguishing points,
a minimum distance between reduced points, and/or
a maximum standardized error of the squares of the distance between starting points (thus the original data points of the measurement progression MV) and reduced points.

As already mentioned, following the application of the algorithm, optionally including additional (secondary) conditions, further criteria can be used for the actual selection of the second distinguishing points P_{M,i}.

An example of a further criterion for (further) reducing the point set would be that a point from the reduced progression is only included as a distinguishing point if e.g. the angle between two straight lines (connecting lines) of a kink (of a point of the reduced point set) has a certain size.

For this purpose, the angle between the two connecting lines, which can be described by vectors v̅e̅c̅1̅ and v̅e̅c̅2̅, can be calculated for each of the seven kinks (points of the point set reduced by means of the RDP algorithm). The angles between the vectors can be calculated by means of the following formula.

$$α = \frac{acos [ ( \vec{vec 1} * \vec{vec 2} ) / ( \vert \vec{vec 1} \vert * \vert \vec{vec 2} \vert ) ]}{2 * π} * 360 °$$

Here, a denotes the angle between two vectors v̅e̅c̅1̅ and v̅e̅c̅2̅. All angles for all kinks from the reduced progression can be calculated with this formula. For this purpose, the two vectors v̅e̅c̅1̅ and v̅e̅c̅2̅ which describe the kink are calculated for each kink and then the angle between the two vectors is calculated, with the aid of the above formula.

Here, the criterion can be introduced that a point resulting from the reduction is only used as one of the second distinguishing points P_{M,i} when the angle between two vectors has a certain size, e.g. less than 170° (or when other formulae are used equivalent to more than 190°).

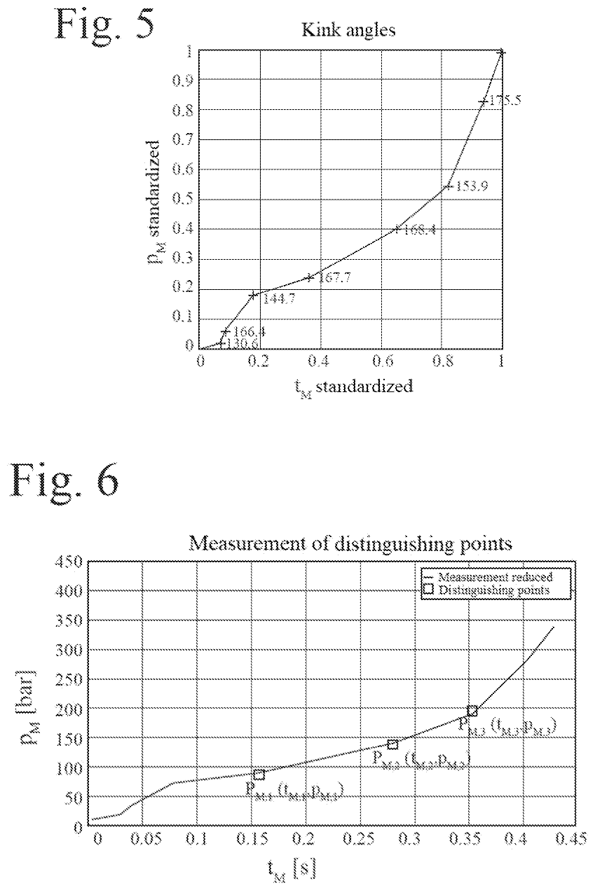

Before the angle calculation is carried out, the measurement progression MV should be standardized both on the X axis and the Y axis. If the angles of the kinks are subsequently calculated and the corresponding angle is plotted in the graph for each kink, the graph from FIG. 5 is obtained, wherein the calculated angle (kink angle) and the corresponding connecting lines are drawn in for each of the points from the reduced point set.

By applying the criterion addressed above that the angle between the vectors at a kink has to be less than 170°, in this example the last point is omitted as a distinguishing point.

In the present embodiment example, the standardization was reversed again, i.e. scaled back again, at this point.

Furthermore, the initial range is not to be included in the analysis for finding distinguishing points, since this is the range in which the non-return valve closes. The simulation (using current simulation software) deviates from the measurement progression MV in this initial range since it is assumed in the simulation that the non-return valve is 100% closed before the injection process, and therefore a different pressure progression compared with the measurement results.

In this respect, the criterion can be set, for example, that the pressure progression is only used for the analysis from a certain pressure threshold (e.g. from 80 bar) and/or from a certain time (e.g. 75 ms) after the start of injection. Further possible additional or alternative further criteria would be, for example, that the first 10% (relative to the time and/or screw position) after the start of injection are omitted or that, knowing the required stroke until the non-return valve is closed, for example twice the required stroke is set as criterion. Moreover, the range up to the time at which a certain adjusted injection volume flow rate was reached could be excluded, for example.

In the present embodiment example, if a pressure threshold of 80 bar is set as second criterion, the second distinguishing points P_{M,i} represented in FIG. 6 result for the measurement progression MV.

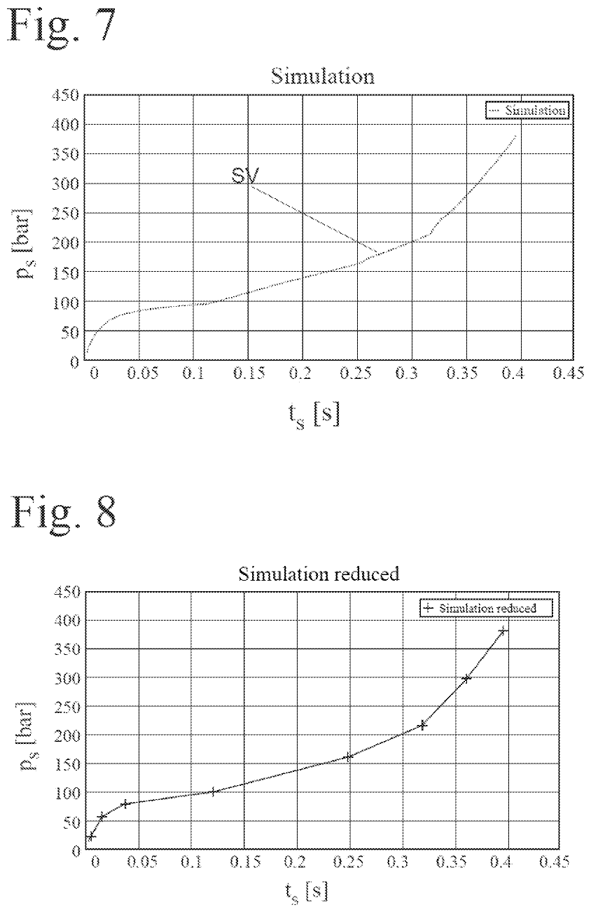

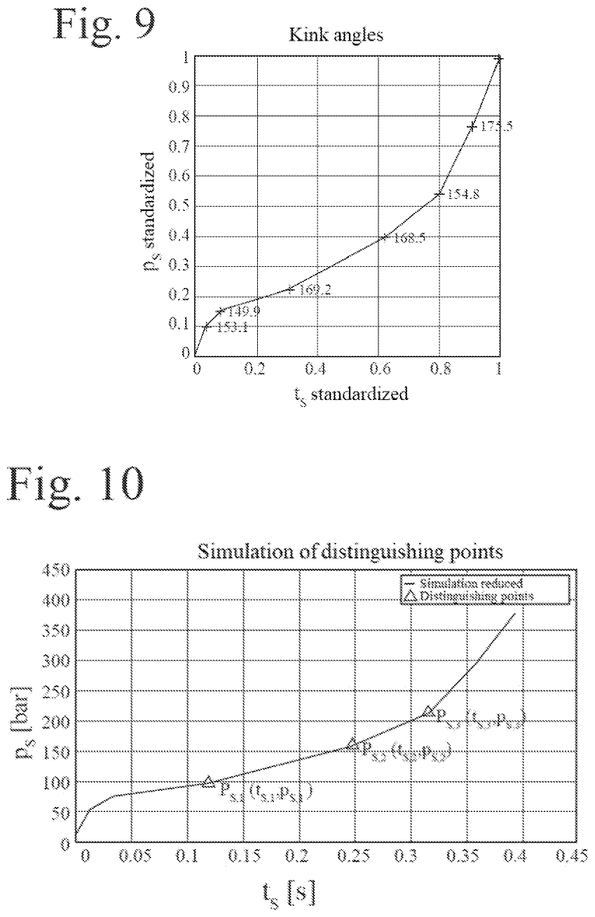

In this embodiment example, finding the first distinguishing points P_{S,i} from the simulation progression SV takes place completely analogously to the procedure described in connection with FIGS. 3 to 6, for which reference is also made to FIGS. 7 to 10. That is to say, all measures which were described in connection with FIGS. 3 to 6 are also provided in the embodiment example according to FIGS. 7 to 10.

Alternatively, the distinguishing points could for example also be found using slope analysis or similar analyses of derivatives.

The first distinguishing points P_{S,i} and the second distinguishing points P_{M,i}, which are represented together in FIG. 14, are the result. The coordinates of the first distinguishing points P_{S,i} are denoted by (t_{S,i}, p_{S,i}) and those of the second distinguishing points P_{M,i} are denoted by (t_{M,i}, p_{M,i}).

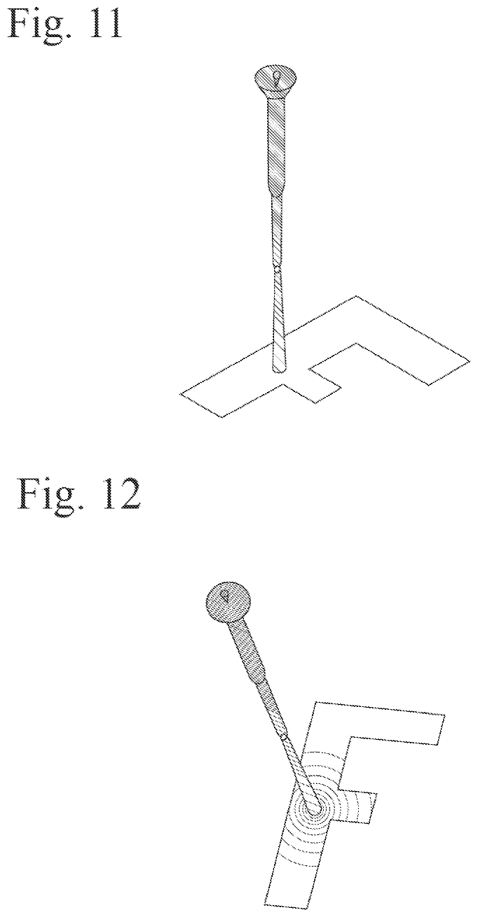

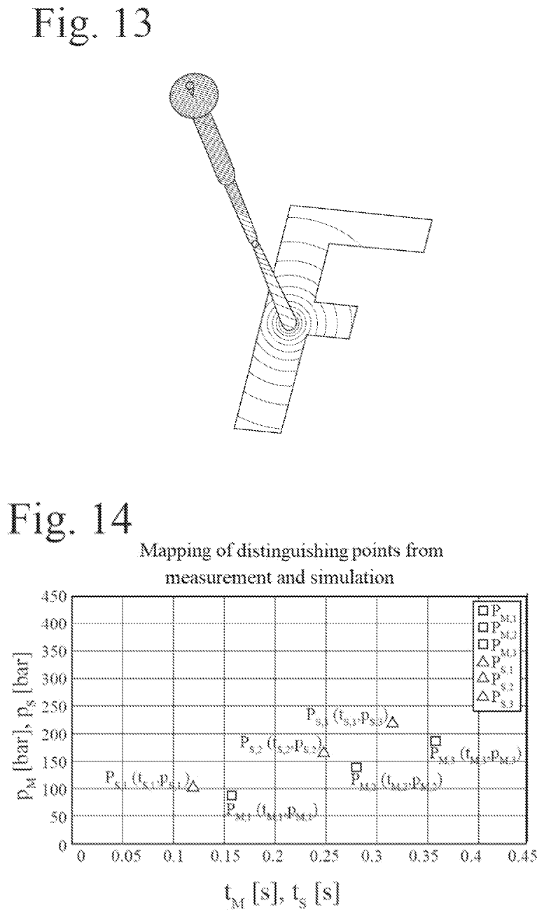

Within the framework of the present injection-molding process, the distinguishing points can be interpreted, for example, as those points in time at which a flow front experiences sudden changes in the resistance to propagation (like meeting obstacles). Visualizations which illustrate these situations can be produced from the simulation carried out and the calculation results thereof as well as the first distinguishing points P_{S,i} determined above. This is represented in FIGS. 11, 12 and 13, wherein
FIG. 11 represents the situation of the first distinguishing point P_{S,i} at the point in time t_{S,i}, wherein the flow front coming from the sprue meets the actual mold cavity,
FIG. 12 represents the situation of the first distinguishing point P_{S,2} at the point in time t_{S,2}, wherein the flow front meets a first end of the cavity, and
FIG. 13 represents the situation of the first distinguishing point P_{S,3} at the point in time t_{S,3}, wherein the flow front meets a second end of the cavity.

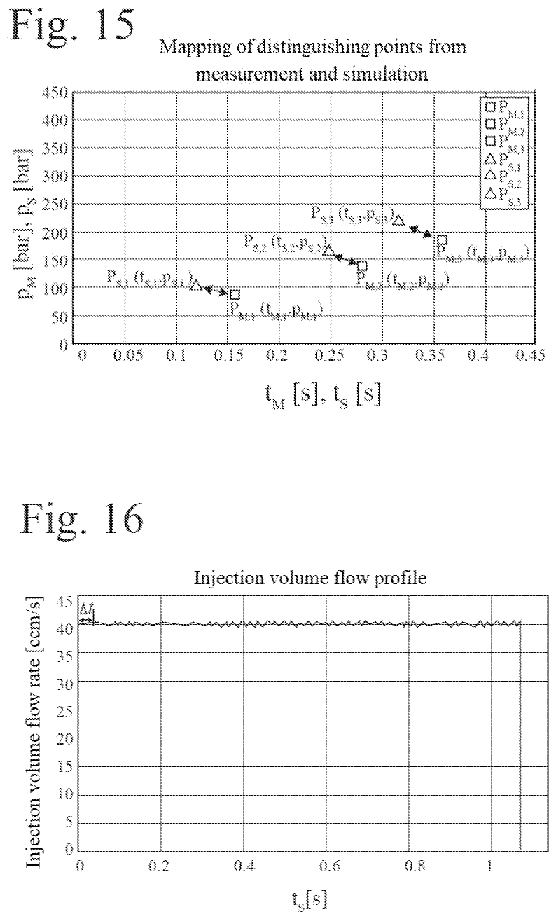

In this embodiment example, it is obvious, at least to human observers, how the in each case three first distinguishing points P_{S,i} and second distinguishing points P_{M,i} should be mapped to each other (see FIG. 15). For less obvious cases, such as will of course occur in reality, a reproducible procedure for finding the “correct” mapping is described further below.

Even if the mapping of the first distinguishing points P_{S,i} and the second distinguishing points P_{M,i} has taken place correctly, these points naturally do not fall on top of each other, i.e. there are deviations which can be detected by means of the (time and pressure) coordinates (t_{S,i}, p_{S,i}) and (t_{M,i}, p_{M,i}).

It should be mentioned that a Cartesian coordinate system was used in the present embodiment example. Naturally, the invention could in principle also be realized with any other desired coordinate system.

According to the invention, a modification parameter is calculated for the simulation by means of the coordinates. Two different examples of modification parameters which can be used for matching the simulation to the process really carried out are given in the following.

Firstly, the time shift which exists between the first distinguishing points P_{S,i} and the second distinguishing points P_{M,i} is dealt with. This can be associated with an injection volume flow rate incorrectly modelled in the simulation.

This can be quantified and compensated for by firstly calculating the arithmetic mean of the time deviations between the points of the first distinguishing points P_{S,i} and the second distinguishing points P_{M,i} mapped to each other:

$$Δ t = \frac{1}{N} {\sum }_{i = 1}^{N} {t}_{M , i} - {t}_{s , i}$$

Instead of the arithmetic mean value, any other desired statistical parameters, such as for example the median, could naturally also be used. It has likewise already been mentioned that instead of a time index an equivalent variable, such as for example a displacement stroke or displacement volume of a plasticizing screw or another actuator, can be used.

The injection volume flow profile modelled in the simulation can be adjusted on the basis of the modification parameter □t. In this embodiment example, the original injection volume flow profile is substantially constant and is represented in FIG. 16.

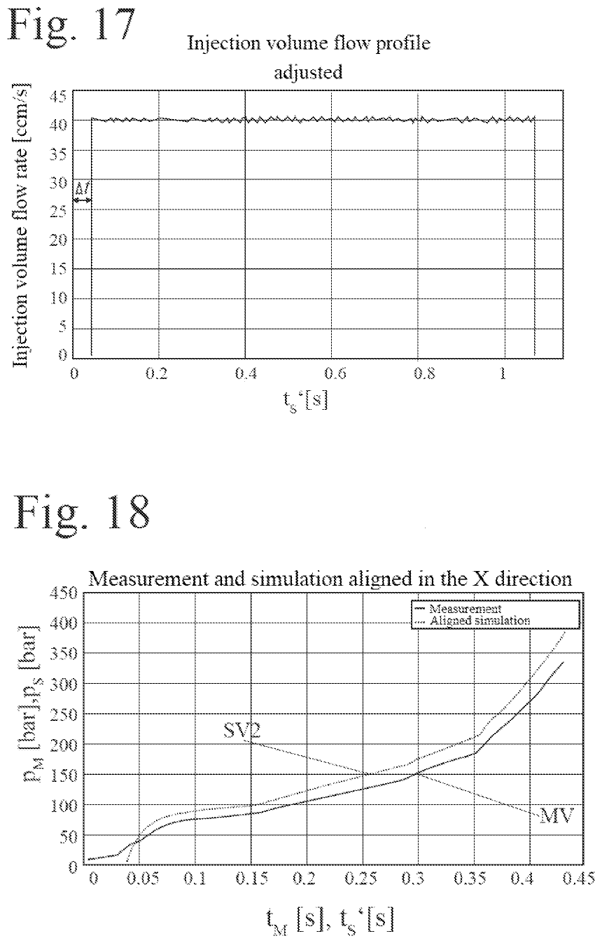

With the aid of the average time shift Δt, this injection volume flow profile can be adjusted such that the time deviation between simulation progression and measurement progression is reduced by, e.g. in the simulation, not allowing the original injection volume flow profile from FIG. 16, which is plotted with the volume flow rate over time, to start from 0 s but rather only from Δt and allowing the values from the starting point to Δt from the original profile to be omitted, which is represented in FIG. 17.

Should the injection volume flow profile not be constant, but rather for example a profile with inclines, etc., it is advisable to compensate for the different injection volume flow rates through corresponding conversion factors when calculating the modification parameter.

Should the plasticizing screw be modelled in the simulation, the position of the plasticizing screw can also be correspondingly adjusted—for example via a position or speed profile.

If the simulation is carried out again with the modified injection volume flow profile represented in FIG. 17, a modified simulation progression SV2, which is represented together with the original measurement progression MV in FIG. 18, results.

As an alternative or in addition to this adjustment of the simulation, the process can also be modified. That is to say, the metering stroke could for example be modified, with the result that the injection volume during the process corresponds to that used in the simulation. Of course, mixed forms are also conceivable, wherein both the metering stroke and the injection volume flow profile modelled in the simulation are modified to a consistent extent in each case.

It can be seen in FIG. 18 that the two curves match up well in terms of time (i.e. the time deviation between the kinks or the distinguishing points from measurement progression MV and simulation progression SV has been greatly reduced), but are still scaled differently in the direction of the y axis. That is to say, although the pressures p_{S,i} in the simulation are consistent relative to each other, they do not have the correct absolute values, which can be caused by an incorrect material model, because material parameters, e.g. used in the simulation, do not correspond to reality.

Therefore the simulation is also still modified, as described below, such that the pressure calculated in the simulation (as variable that is characteristic of the process) better models the pressure actually measured.

In the present embodiment example, for the simulation, a Cross-WLF model was used for the material simulation. The Cross-WLF model gives the melt viscosity 11 of the molding material as follows:

$$η = \frac{{η}_{0}}{1 + {( \frac{{η}_{0} \dot{γ}}{{τ}^{*}} )}^{1 - n}}$$

Therein:
η denotes the melt viscosity in Pa*s,
η₀ denotes the zero shear viscosity in Pa*s,
\dot{γ} denotes the shear velocity (unit 1/s),
τ\hat{ } denotes the critical shear stress at the transition to shear thinning, and
denotes an exponent which describes the shear thinning behavior at high shear rates.

The zero shear viscosity is given by the following equation:

$${η}_{0} = {D}_{1} exp [ - \frac{{A}_{1} ( T - {T}^{*} )}{{A}_{2} + ( T - {T}^{*} )} ]$$

In the following, it is explained how this model is adjusted, so that the simulation can be aligned with the real process.

Firstly, a factor kp is determined from the pressure coordinates p_{S,i} and p_{M,i} of the first and second distinguishing points P_{S,i} and P_{M,i} as follows:

$$kp = \frac{1}{N} {\sum }_{i = 1}^{N} \frac{{p}_{M , i}}{{p}_{s , i}}$$

N here corresponds to the number of first and second distinguishing points P_{S,i} and P_{M,i} and the arithmetic mean of the quotients is thus calculated from p_{M,i} (measured pressure at the i-th second distinguishing point P_{M,i} in the measurement progression MV) over p_{S,i} (simulated/calculated pressure at the i-th first distinguishing point P_{S,i} in the simulation progression SV).

It should be noted that, in contrast to WO 2016/177513 A1, in this way also the coordinates p_{S,i} and p_{M,i}, i.e. thus the simulated and measured pressures, or more generally the simulated and calculated characteristic variable, also actually continue to be used.

Instead, kp could naturally also be defined here via a median or any other desired statistical parameter.

With the aid of the pressure scaling parameter value kp, the simulation can be adjusted such that the pressure deviation between simulation and measurement is reduced. In this case, e.g. the material parameters in the Cross-WLF model can be adjusted on the basis of the parameter kp.

In the present embodiment example, the Cross-WLF model is adjusted by specifying new parameters D₁′ and τ″ using the modification parameter value for kp and defined by

D₁′=D₁×kp

and

τ″=τ′×kp

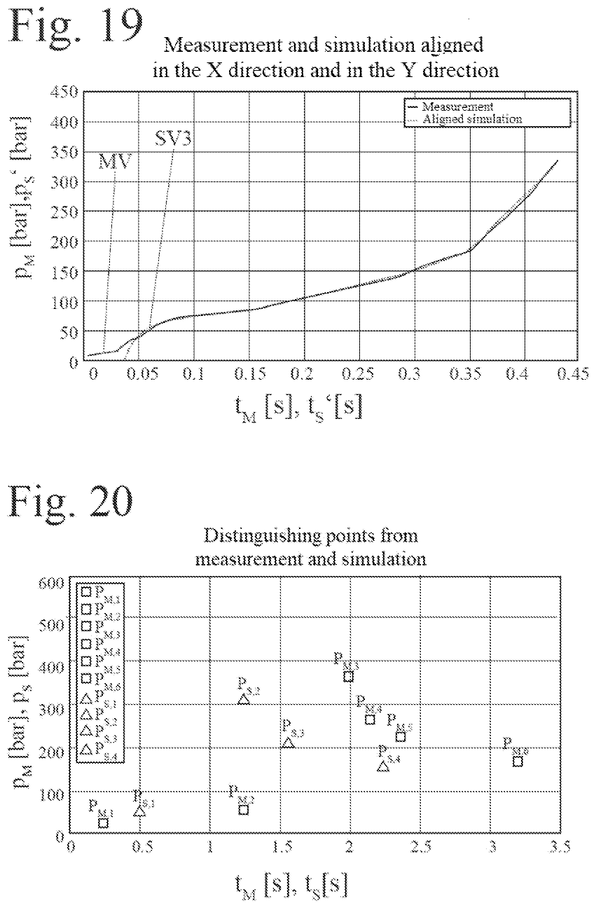

If the simulation is carried out again, wherein this modified material model and the temporal adjustment of the injection volume flow profile, which was described in connection with FIG. 16 and FIG. 17, are taken into account, a simulation progression SV3 that has been modified again is obtained, which is represented together with the original measurement progression MV in FIG. 19. It is obvious that the simulation progression SV3 that has been modified again corresponds very well with the original measurement progression MV and cannot be distinguished from the measurement progression MV at all over large parts of the curves. (Of course, the pressure scaling would also be improved correspondingly if only the material model is adjusted and the injection volume flow profile were maintained).

An effective alignment between the actual measurement and the simulation was thus brought about without having to carry out a large number of simulations.

The deviating scaling of the (optionally modified) measurement progression MV and of the (optionally modified) simulation progression (see e.g. FIG. 18) could also be compensated for by modifying the process. For example by reducing the molding material temperature, the viscosity of the molding material can be increased. As a result, the pressure p_{M} will rise more quickly, which brings the (optionally modified) measurement progression MV closer to the (optionally modified) simulation progression SV.

The time shift or the scaling of the pressure are only two examples. Naturally, more complicated calculations on the basis of the first and second distinguishing points mapped to each other are also possible. Thus, for example, the difference in the dead volume (thus the melt volume in the flange, nozzle or hot runner not accessible by the screw movement) between simulation and measurement could be calculated from these points.

Likewise, several simulations and several measurements with different boundary conditions can also be considered at the same time in order to be able to take the dependencies on these boundary conditions into account when calculating the modification parameters. Such boundary conditions can be, for example, a forming mass temperature, a tool temperature or all other parameters taken into account in the simulation.

Instead of using an arithmetic mean, the modification parameters based on the first and second distinguishing points can also be calculated for example using optimization algorithms or regression methods.

It is obvious that a thus-aligned simulation can be extremely helpful when setting the injection-molding process—or in general in processes carried out with shaping machines.

In the following it will now be discussed how the first distinguishing points P_{S,i} and the second distinguishing points P_{M,i} can be mapped to each other reproducibly.

In the example presented here for this purpose, we assume that four first distinguishing (simulation) points (P_{S} for short) were found in the simulation and six second distinguishing (measurement) points (P_{M} for short) were found in the measurement, wherein the indices i are only still noted if this is necessary for understanding, for the sake of simplicity. The points for this example are represented in the graph in FIG. 20.

Without restricting generality, the four first distinguishing points P_{S} from the simulation progression SV are mapped onto the four “ideal” second distinguishing points P_{M} from the possible total of six from the measurement progression MV using the procedure presented. Conversely, this means that if more first distinguishing points P_{S} than second distinguishing points P_{M} were present, this would naturally also be possible. Typically, however, it can be assumed that more distinguishing points will be obtained in the measurement than in the simulation, since in most real cases certain geometries, such as e.g. space in front of the screw, nozzle, etc., are not modelled in the simulation, but are reflected in the measurement progression MV.

In principle, the procedure is as follows:
1.) In the first step, it is assumed that the number k of first distinguishing points P_{S} from the simulation progression SV is smaller than the number n of second distinguishing points P_{M} from the measurement progression MV. Ultimately this means that k first distinguishing points P_{S} from the simulation progression SV are mapped onto n second distinguishing points P_{M} from the measurement progression MV (wherein in principle n>k second distinguishing points P_{M} would be present).
2.) The k first distinguishing points P_{S} from the simulation progression SV are always compared with n second distinguishing points P_{M} from the measurement progression MV. All possible combinations in the selection of k first distinguishing points P_{S} from n second distinguishing points P_{M} from the measurement progression MV are tested. In our example, the possible combinations of four out of six points are thus tested irrespective of the sequence.

The number of possible mappings of the four P_{S} onto the six P_{M} can be calculated using the following known formula from combinatorics.

$$\frac{n !}{( n - k ) ! * k !} = \frac{6 !}{( 6 - 4 ) ! * 4 !} = 15$$

15 possible combinations of the mapping of four P_{S} to six present P_{M} are possible according to this. The possible combinations of how the four P_{S} can be mapped onto the six P_{M} (see FIG. 20) are listed in the following table.

| Combination | P_{M, 1} | P_{M, 2} | P_{M, 3} | P_{M, 4} | P_{M, 5} | P_{M, 6} |
|---|---|---|---|---|---|---|
| 1 | X | X | X | X | | |
| 2 | | X | X | X | X | |
| 3 | | | X | X | X | X |
| 4 | X | | X | X | X | |
| 5 | X | | | X | X | X |
| 6 | | X | | X | X | X |
| 7 | X | X | | X | X | |
| 8 | X | X | | | X | X |
| 9 | X | X | | X | | X |
| 10 | X | X | X | | X | |
| 11 | X | X | X | | | X |
| 12 | | X | X | | X | X |
| 13 | | X | X | X | | X |
| 14 | X | | X | X | | X |
| 15 | X | | X | | X | X |

All 15 possible combinations are now tested and the combination in which the first distinguishing points P_{S} from the simulation progression and the second distinguishing points P_{M} from the measurement progression MV are best mapped to each other, which is the desired result, is chosen.

In order to be able to explain the procedure in an understandable manner, it is applied by way of example in the combinations 1 and 12 from the above table in the following.

In combination 1, the first four distinguishing points (P_{M,1}, P_{M,2}, P_{M,3} and P_{M,4}) from the measurement progression MV are used.

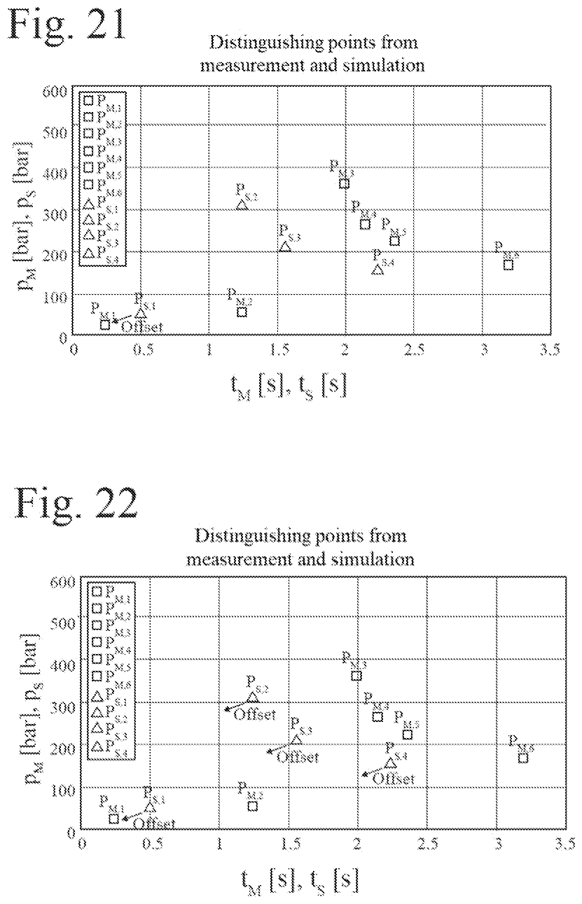

Firstly, the first occurring distinguishing point P_{S,i} of the simulation progression SV is shifted onto the first distinguishing point P_{M,i} of the measurement progression MV with an offset (vector with X component oₓ and Y component o_{y}) (see FIG. 21).

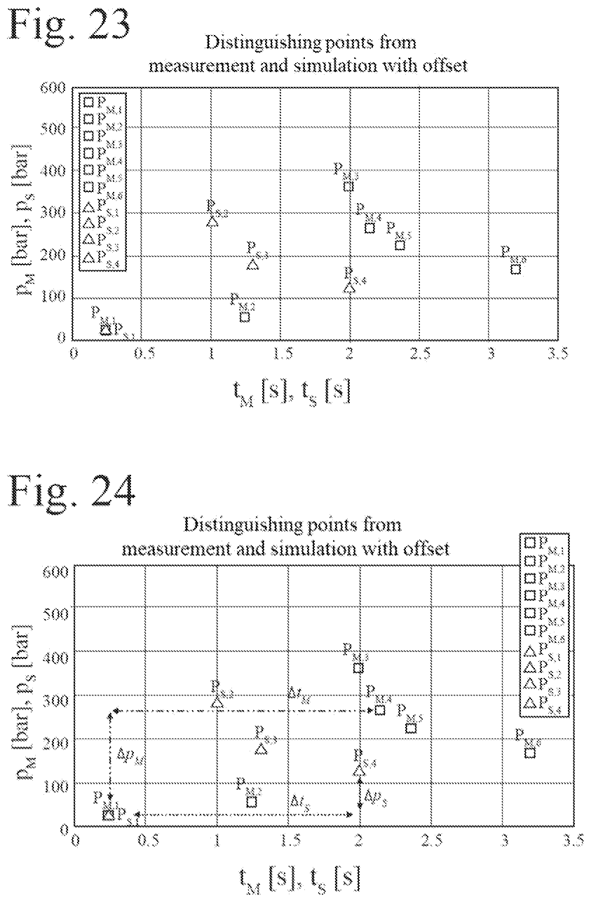

The remaining distinguishing points P_{S,i}, with i equal to 2, 3 and 4, from the simulation progression SV are shifted by the same offset (see FIG. 22). The result is represented in FIG. 23, wherein the two first in each case of the first distinguishing points P_{S,i} and of the second distinguishing points P_{M,i} lie on top of each other. The remaining distinguishing points from the simulation progression SV were shifted by the offset.

Referring to FIG. 24, next the coordinate differences Δt_{M} and Δp_{M} between the second distinguishing point P_{M,4} (with index 4) and the corresponding second distinguishing point P_{M,1} (index 1) from the measurement progression MV relevant for combination 1 and the corresponding coordinate differences Δt_{S} and Ops between the first distinguishing point P_{S,4} (index 4) and the first distinguishing point P_{S,1}, with index 1, from the simulation progression SV are calculated.

Scaling parameters kₓ and k_{y} are then calculated therefrom using the following formulae.

$${k}_{x} = \frac{Δ {t}_{M}}{{Δt}_{s}} and {k}_{y} = \frac{Δ {p}_{M}}{Δ {p}_{s}}$$

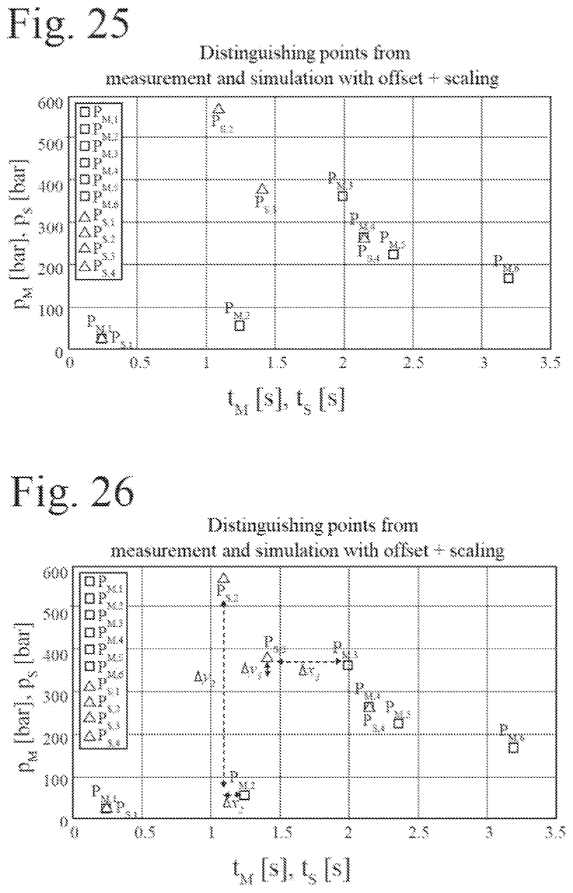

Then, for the three second distinguishing points P_{S,2}, P_{S,3} and P_{S,4}, in each case the coordinate differences in the x as well as y direction with respect to the second distinguishing point P_{S,1} with index 1 are calculated. In the framework of a rescaling, for each of the three points P_{S,2}, P_{S,3} and P_{S,4}, then the calculated x coordinate difference is multiplied by the scaling parameter kₓ as well as the calculated y coordinate difference is multiplied by the scaling parameter k_{y} (and in each case added to the coordinates t_{S,1} and p_{S,1}). These newly formed coordinates are used as coordinates for points P_{S,2}, P_{S,3} and P_{S,4} shifted according to the rescaling. This then results in the graph from FIG. 25, wherein in each case the first and second distinguishing points P_{S,i} and P_{M,i} with indices 1 and 4 from the measurement progression MV and the simulation progression SV lie on top of each other. The other distinguishing points from simulation and measurement may (and will generally) differ.

Now, the differences (Δxᵢ, Δyᵢ) in the x as well as y direction of the distinguishing points from the simulation progression SV and the measurement progression MV, in each case occurring in the same sequence, are calculated (see FIG. 26). That is to say, the first distinguishing point P_{S,2} (with index 2) is compared with the second distinguishing point P_{M,2} (likewise index 2) from the chosen combination (combination 1 in this case) of distinguishing points from the measurement progression (for the purpose of a coordinate difference calculation) and accordingly P_{S,3} is also compared mit P_{M,3} here. If, for example, P_{M,2} were not contained in combination 1, P_{M,3} would simply be used according to the sequence if it is present in the corresponding combination.

A characteristic number f (or several characteristic numbers) can be calculated from the calculated offset (oₓ,o_{y}), the scaling parameters kₓ and k_{y} and the differences (Δxᵢ,Δyᵢ) as quality criterion for the correspondence of the points in combination 1 mapped to each other in the form of function ƒ(Δxᵢ, Δyᵢ,kₓ,k_{y},oₓ,o_{y}). The calculation of this characteristic number can be carried out analogously for each of the 15 possible combinations. In this connection, the different parameters can be weighted differently using weighting factors.

The characteristic number could be calculated e.g. as follows:

$$f ( Δ {x}_{i} , Δ {y}_{i} , {k}_{x} , {k}_{y} , {o}_{x} , {o}_{y} ) = {g}_{1} {\sum }_{i = 1}^{k} ( Δ {x}_{i}^{2} + Δ {y}_{i}^{2} ) + {g}_{2} ( {( {k}_{x} - 1 )}^{2} + {( {k}_{y} - 1 )}^{2} ) + {g}_{3} ( {o}_{x}^{2} + {o}_{y}^{2} )$$

g₁, g₂ and g₃ are the weighting factors. If e.g. g₁=1 and g₂=g₃=0 are set, the following shorter formula results for the calculation of the characteristic number:

$$f ( Δ {x}_{i} , Δ {y}_{i} ) {\sum }_{i = 1}^{k} ( Δ {x}_{i}^{2} + Δ {y}_{i}^{2} )$$

The procedure for mapping the distinguishing points is explained once again with reference to combination 12 from the above table. In this case, it involves the combination with the best correspondence during the mapping (thus the “ideal” combination with the best quality of the mapping).

In the case of this combination 12, the second distinguishing points P_{M,2}, P_{M,3}, P_{M,5} and P_{M,6} (i.e. with indices 2, 3, 5 and 6) from the measurement progression MV and of course all first distinguishing points P_{S,i} with indices 1 to 4 are used for the mapping (see FIG. 20).

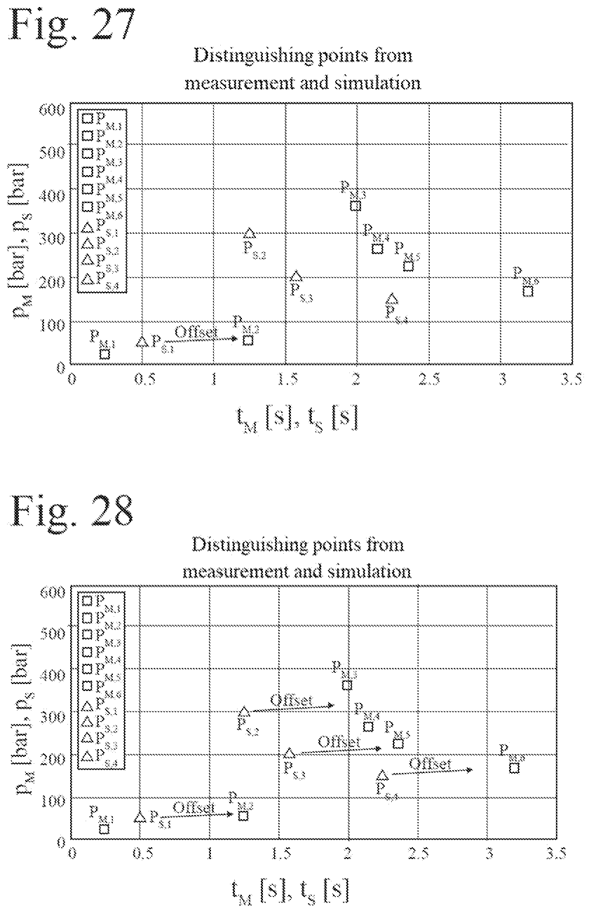

Firstly, the first distinguishing point P_{S,i} with index 1 of the simulation progression SV is shifted onto the second distinguishing point P_{M,2} with index 2 of the measurement progression MV with an offset (see FIG. 27).

The remaining first distinguishing points P_{S,i} from the simulation progression SV relevant for combination 12 are shifted by the same offset, which is illustrated in FIG. 28.

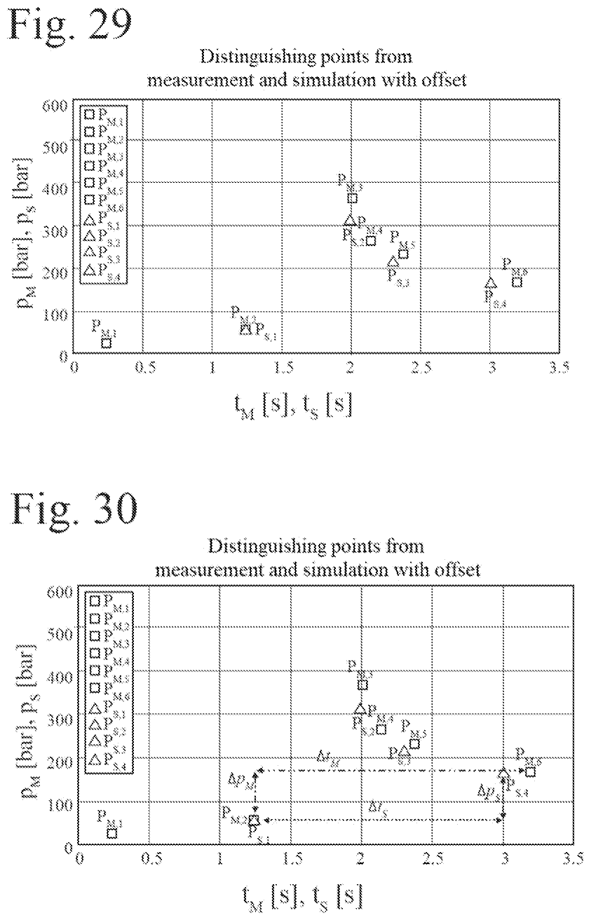

This results in the graph from FIG. 29, wherein P_{M,2} from the measurement progression MV and P_{S,i} from the simulation progression SV lie on top of each other and the three remaining first distinguishing points P_{S,i} from the simulation progression SV have been shifted by the offset.

As is illustrated in FIG. 30, next the coordinate differences Δt_{M} and Δp_{M} between the second distinguishing point P_{M,6} (index 6) and the second distinguishing point P_{M,2} (with index 2) from the measurement progression MV as well as the coordinate differences Δt_{S} and Aps between the first distinguishing point P_{S,4} (index 4) and the first distinguishing point P_{S,1} (index 1) from the simulation progression SV are calculated (analogously to the description in connection with FIG. 24).

The scaling parameters kₓ and k_{y} are then calculated using the already known following formulae.

$${k}_{x} = \frac{Δ {t}_{M}}{Δ {t}_{s}} and {k}_{y} = \frac{Δ {p}_{M}}{Δ {p}_{s}}$$

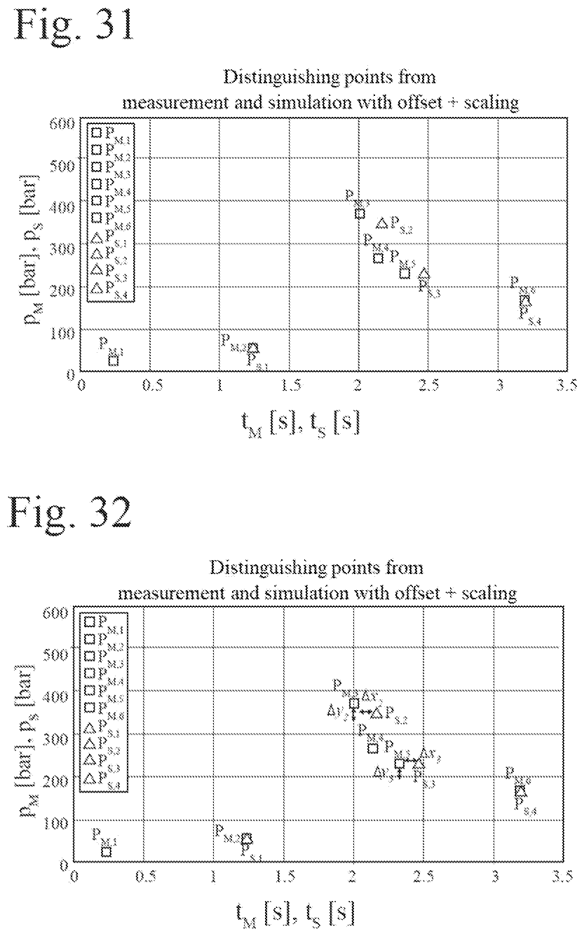

Analogously to the description in connection with FIG. 25, for the three second distinguishing points P_{S,2}, P_{S,3} and P_{S,4}, in each case the coordinate differences in the x as well as y direction with respect to the second distinguishing point P_{S,1} with index 1 are calculated. In the framework of a rescaling, for each of the three points P_{S,2}, P_{S,3} and P_{S,4}, then the calculated x coordinate difference is multiplied by the scaling parameter kₓ as well as the calculated y coordinate difference is multiplied by the scaling parameter k_{y} (and in each case added to the coordinates t_{S,1} and p_{S,1}). These newly formed coordinates are used as coordinates for points P_{S,2}, P_{S,3} and P_{S,4} shifted according to the rescaling. This then results in the graph from FIG. 31, wherein in each case the distinguishing points P_{S,i} and P_{M,2} as well as P_{S,4} and P_{M,6} lie on top of each other. The other distinguishing points from simulation and measurement may (and will generally) differ.

Now, the differences (Δxᵢ, Δyᵢ) in the x as well as y direction of the distinguishing points from the simulation progression SV and the measurement progression MV, in each case occurring in the same sequence, are calculated (see FIG. 32 by analogy with FIG. 26). That is to say, P_{S,2} is compared with point P_{M,3} from the chosen combination (combination 12 in this case) (for the purpose of a coordinate difference calculation) and accordingly P_{S,3} is also compared with P_{M,5}. As mentioned, the parameters (Δxᵢ, Δyᵢ) are drawn in in the graph from FIG. 32 for better understanding.

Also in this case, the same characteristic number for the correspondence of the points mapped to each other in combination 12 can be calculated in the form of function ƒ(Δxᵢ,Δyᵢ,kₓ,k_{y},oₓ,o_{y}) (see above). With the same weighting of the parameters g₁=1 and g₂=g₃=0, it can easily be recognized in this example that the differences (Δxᵢ, Δyᵢ) turn out to be much smaller than in combination 1 described previously (compare FIG. 26 with FIG. 32).

If this procedure were used to go through all 15 combinations, it would be concluded that combination 12 generates the best correspondence/quality—i.e. the lowest characteristic number f—and can accordingly carry out the mapping of the first distinguishing points P_{S,i} with the indices 1, 2, 3 and 4 from the simulation progression SV to the second distinguishing points P_{M,i} with the indices 2, 3, 5 and 6 from the measurement progression MV (in this sequence, thus 1->2, 2->3, 3->5 and 4->6).

Self-evidently, instead of the first distinguishing points P_{S,i} the second distinguishing points P_{M,i} can also be shifted and rescaled according to the described procedure, without modifying the combination with the best quality of the mapping determined on the basis of the calculated characteristic numbers.

One advantage of the described procedure for mapping the first distinguishing points P_{S,i} and the second distinguishing points P_{M,i} is that it can be implemented as an algorithm e.g. as part of a computer program.

In the above-indicated formulae for the modification parameters kp and Δt, it can of course be advantageous to add up only via those indices i which actually occur in that combination (in the example here for the general procedure for working out the mapping this would be combination 12) for which the best (here lowest) characteristic number was calculated.

1. A method for aligning a simulation of a process to be carried out with a shaping machine with the process really carried out, wherein
within the framework of the simulation at least one simulation progression of a variable that is characteristic of the process, in particular a simulated pressure progression, is calculated,
in the process really carried out at least one measurement progression (MV) of the characteristic variable, in particular a measured pressure progression, is measured,
first distinguishing points of the curve of the at least one simulation progression and second distinguishing points of the curve of the at least one measurement progression are determined,
the first distinguishing points and the second distinguishing points are at least partially mapped to each other,
at least one modification parameter for the simulation and/or the process is calculated from coordinates of the first distinguishing points and second distinguishing points at least partially mapped to each other, and
the simulation and/or the process is modified on the basis of the at least one modification parameter and carried out again.

2. The method according to claim 1, wherein the first distinguishing points and/or the second distinguishing points are determined using the Ramer-Douglas-Peucker algorithm, wherein at least one additional criterion is preferably used to further reduce a point set reduced using the Ramer-Douglas-Peucker algorithm in order to obtain the first distinguishing points and/or the second distinguishing points.

3. The method according to aclaim 1, wherein the first distinguishing points and/or the second distinguishing points are accordingly determined, if connecting lines to adjacent points of the simulation progression or of the measurement progression form an angle which deviates by a predefined angular amount—preferably by 5° or more, particularly preferably by 10° or more-from 180°.

4. The method according to claim 2, wherein at least one of the following conditions and/or criteria is used when determining the first distinguishing points and/or the second distinguishing points:
a maximum number of reduced points and/or distinguishing points,
a minimum distance between the points of the reduced point set,
a maximum standardized error of the squares of the distance between the original data points of the measurement progression and/or of the simulation progression on the one hand and the points of the reduced point set on the other,
exceeding and/or reaching a threshold value through the characteristic variable,
excluding a predefined partial range of the process, wherein the partial range is given by absolute or relative limits.

5. The method according to claim 1, wherein the first distinguishing points and the second distinguishing points are at least partially mapped to each other, in that
for all of the possible different options for mapping the first distinguishing points to the second distinguishing points, the first distinguishing points-WO and/or the second distinguishing points are scaled and/or shifted such that in each case two of the first distinguishing points and of the second distinguishing points substantially lie on top of each other,
in each case at least one characteristic number for the quality of the respective mapping option is calculated on the basis of at least one of the following: scaling parameter, shifting parameter, coordinate differences between the—optionally scaled and/or shifted—first distinguishing points and the—optionally scaled and/or shifted—second distinguishing points,
that mapping option is selected, at least one characteristic number of which indicates a best quality of the mapping.

6. The method according to claim 1, wherein the method is applied to results of the simulation carried out again and/or to measurements in the process carried out again, wherein this is preferably repeated until a simulation deviation between the at least one simulation progression and the at least one measurement progression is sufficiently small according to a predefined criterion.

7. The method according to claim 6, wherein the loop started by applying the method again is interrupted if:
values of the at least one modification parameter reach and/or fall below a first predefined limit value, and/or
differences—in particular differences in amount—from areas under the at least one simulation progression and the at least one measurement progression reach and/or fall below a second predefined limit value, and/or
the at least one simulation progression at least partially—preferably completely—proceeds within a predefined first tolerance range around the at least one measurement progression, and/or
the at least one measurement progression at least partially—preferably completely—proceeds within a predefined second tolerance range around the at least one simulation progression.

8. The method according to claim 1, wherein the at least one modification parameter relates to a magnitude of a time shift between the first distinguishing points and second distinguishing points mapped to each other, wherein the time shift is in particular caused by an unknown volume of the molding material present in the shaping machine.

9. The method according to claim 8, wherein the simulation is modified by modifying an injection volume predefined for the simulation and/or an injection volume flow rate predefined for the simulation on the basis of the at least one modification parameter for the magnitude of the time shift.

10. The method according to claim 1, wherein the at least one modification parameter relates to a magnitude of a scaling of those coordinates of the first distinguishing points and second distinguishing points mapped to each other which correspond to the characteristic variable.

11. The method according to claim 10, wherein the simulation is modified by modifying a material parameter predefined for the simulation on the basis of the at least one modification parameter for the magnitude of the scaling.

12. The method according to claim 1, wherein the at least one modification parameter is calculated as a statistical parameter, in particular arithmetic mean, of the coordinates of the first distinguishing points and second distinguishing points at least partially mapped to each other.

13. The method according to claim 1, wherein a Cross-WLF model and/or a 2-domain Tait pvT model is used as material model for the simulation.

14. The method according to claim 1, wherein the at least one modification parameter is stored in a database and is used when simulating and/or setting a separate process.

15. The method according to claim 1, wherein several simulation progressions and/or several measurement progressions are taken into account when determining the first distinguishing points and/or the second distinguishing points.

16. The method according to claim 1, wherein the at least one simulation progression and/or the at least one measurement progression are parameterized by means of a time index or a position index of an actuator used in the process, in particular of a plasticizing screw.

17. A shaping machine, which is set up to carry out the method according to claim 1.

18. A computer program product for aligning a simulation of a process to be carried out with a shaping machine with the process really carried out, with commands which prompt a computer executing them
to calculate at least one simulation progression of at least one variable that is characteristic of the process, in particular a simulated pressure progression, within the framework of a simulation or to receive one from a separate simulation,
to receive at least one measurement progression of the at least one characteristic variable, in particular a measured pressure progression, from the real process,
to determine first distinguishing points of the curve of the at least one simulation progression and second distinguishing points of the curve of the at least one measurement progression,
to at least partially map the first distinguishing points and the second distinguishing points to each other,
to calculate at least one modification parameter for the simulation and/or the process from coordinates of the first distinguishing points and second distinguishing points at least partially mapped to each other, and
to modify either the simulation and/or the process on the basis of the at least one modification parameter and to carry it out again
or to output instructions which include that the simulation and/or the process is to be carried out again and what modifications are to be made to the simulation and/or the process on the basis of the at least one modification parameter.
